(19) United States
(12) Patent Application Publication
(10) Pub. No.: US 2022/0302671 A1
(43) Pub. Date: Sep. 22, 2022

(54) OPTICAL MODULE

(71) Applicant: CIG Photonics Japan Limited, Kanagawa (JP)

(72) Inventors: Daisuke NOGUCHI, Tokyo (JP); Hiroshi YAMAMOTO, Tokyo (JP)

(21) Appl. No.: 17/667,615

(22) Filed: Feb. 9, 2022

(30) Foreign Application Priority Data
Mar. 18, 2021 (JP) 2021-044440

(51) Int. Cl. H01S 5/0232; H01S 5/02253; H01S 5/02255

(52) U.S. Cl. CPC H01S 5/0232; H01S 5/02253; H01S 5/02255

(57) ABSTRACT

An optical module includes: a conductive stem having first and second surfaces; some lead pins including a signal lead pin; a sub-mount substrate having an interconnection pattern; a photoelectric device mounted on the sub-mount substrate and electrically connected to the interconnection pattern; a dielectric block having a metallization pattern on a surface; and a signal wire electrically connecting the metallization pattern to the interconnection pattern. Each lead pin includes a shaft portion inside a corresponding one of the through holes, a first end portion projecting from the first surface, and a second end portion projecting from the second surface. The signal lead pin has the first end portion larger in diameter than the shaft portion. The dielectric block is opposed to and fixed to a tip face of the first end portion of the signal lead pin. The metallization pattern is electrically continuous to the tip face.

### CROSS-REFERENCE TO RELATED APPLICATION

The present application claims priority from Japanese patent application JP2021-044440 filed on Mar. 18, 2021, the contents of which are hereby incorporated by reference into this application.

### BACKGROUND

### 1. Field

This disclosure relates to an optical module.

### 2. Description of the Related Art

Small optical modules are required to have improved high-frequency characteristics. A transistor outline can (TO-CAN) package (JP 2011-108939A) uses lead pins to transmit electrical signals to an edge emitting laser. Each lead pin penetrates a conductive stem with a dielectric interposed between them to form a coaxial line.

Bonding wires are used to make electrical connections from the lead pins. A shorter bonding wire has its lower impedance, while the lead pin should protrude longer from the conductive stem to use the shorter bonding wire. This results in a higher impedance and degrades high-frequency characteristics.

### SUMMARY

This disclosure aims to improve the high frequency characteristics.

An optical module includes: a conductive stem having a first surface and a second surface, the conductive stem having some through holes penetrating between the first surface and the second surface; some lead pins including a signal lead pin, the lead pins being located inside the respective through holes, the lead pins being secured to and insulated from the conductive stem with a dielectric; a sub-mount substrate having an interconnection pattern, the sub-mount substrate being at least indirectly fixed to the first surface; a photoelectric device mounted on the sub-mount substrate and electrically connected to the interconnection pattern, the photoelectric device being configured to convert an optical signal and an electrical signal at least from one to another; a dielectric block having a metallization pattern on a surface; and a signal wire electrically connecting the metallization pattern to the interconnection pattern of the sub-mount substrate. Each of the lead pins includes a shaft portion inside a corresponding one of the through holes, a first end portion projecting from the first surface, and a second end portion projecting from the second surface. The signal lead pin has the first end portion larger in diameter than the shaft portion. The dielectric block is opposed to and fixed to a tip face of the first end portion of the signal lead pin. The metallization pattern is electrically continuous to the tip face.

The metallization pattern is on the surface of the dielectric block, whereby impedance can be lowered due to capacitance of the dielectric block. This can improve the high-frequency characteristics.

### BRIEF DESCRIPTION OF THE DRAWINGS

FIG. 1 is a side view of an optical module according to a first embodiment.

FIG. 2 is perspective view of a conductive stem and electronic components mounted on it.

FIG. 3 is a plan view of the conductive stem and the electronic components mounted on it.

FIG. 4 is a IV-IV cross-sectional view of a structure in FIG. 3.

FIG. 5 is an exploded perspective view of the optical module.

FIG. 6 is a perspective view of a conductive stem and electronic components mounted on it according to a second embodiment.

FIG. 7 is frequency characteristics of a comparative example, the first embodiment, and the second embodiment, calculated by a three-dimensional electromagnetic field simulator HFSS (High Frequency Structure Simulator).

### DETAILED DESCRIPTION

The embodiments of the present invention will be described in detail and concretely with reference to the drawings below. In all the figures, the parts with the same sign have the same or equivalent functions, and the repetition of the description is omitted. The size of the figures does not necessarily correspond to the magnification.

### First Embodiment

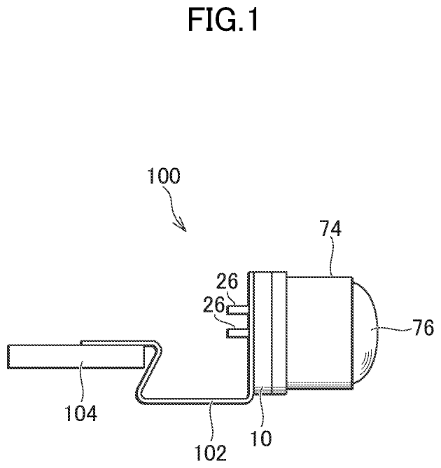

FIG. 1 is a side view of an optical module according to a first embodiment. An optical module 100 is a TO-CAN (Transistor Outline-Can) type optical module and may be any one of a transmitter optical sub-assembly (TOSA) equipped with a light emitting device, a receiver optical sub-assembly (ROSA) equipped with a light receiving device, and a bidirectional module (BOSA) equipped with both the light emitting device and the light receiving device. The optical module 100 has a flexible printed circuit board (FPC) 102, which is connected to a printed circuit board (PCB) 104. The optical module 100 has a conductive stem 10.

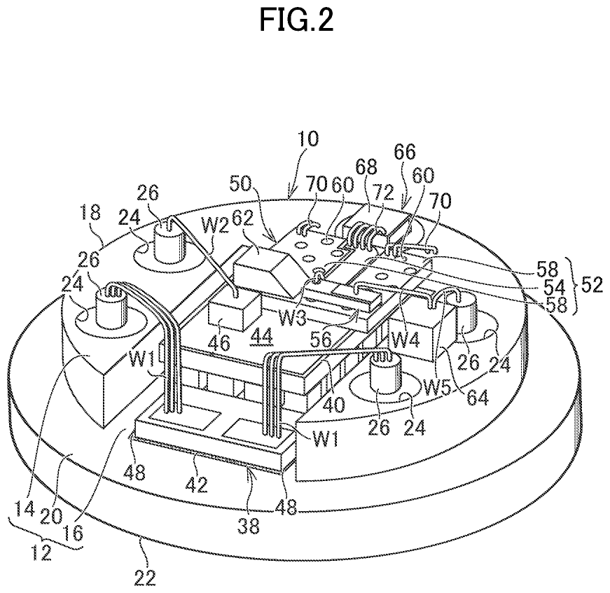

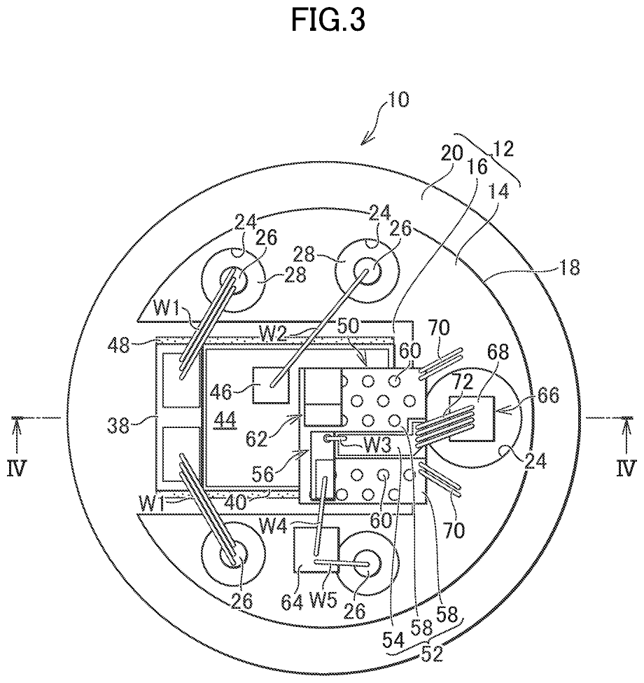

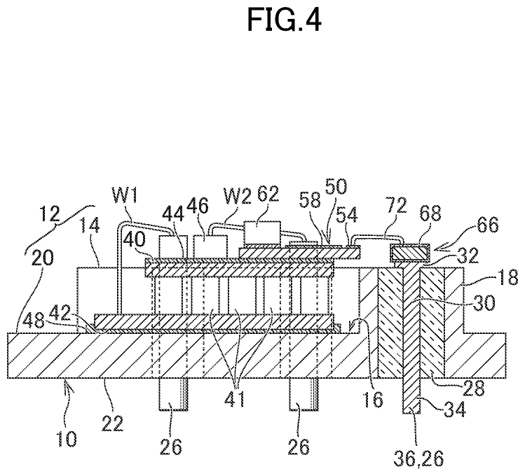

FIG. 2 is perspective view of a conductive stem 10 and electronic components mounted on it. FIG. 3 is a plan view of the conductive stem 10 and the electronic components mounted on it. FIG. 4 is a IV-IV cross-sectional view of a structure in FIG. 3.

### [Conductive Stem]

The conductive stem 10 is made of a conductor such as metal. The conductive stem 10 is connected to a reference potential (e.g., ground). The conductive stem 10 includes an eyelet.

The conductive stem 10 has a first surface 12. The first surface 12 of the conductive stem 10 includes a reference area 14. The first surface 12 includes a mounting area 16 that is lower than the reference area 14. The first surface 12 has a projection 18 around the mounting area 16. An upper surface of the projection 18 is the reference area 14. The first surface 12 includes, around the projection 18, a peripheral area 20 lower than the reference area 14. The projection 18 is inside the peripheral area 20.

The conductive stem 10 has a second surface 22. The second surface 22 is flat. The conductive stem 10 has some through holes 24 that penetrate between the first surface 12 and the second surface 22. The through holes 24 are formed in the reference area 14.

### [Lead Pins]

The optical module 100 has some lead pins 26. The lead pins 26 are arranged in the reference area 14. The lead pins 26 are located inside the respective through holes 24. The lead pins 26 are fixed to and insulated from the conductive stem 10 with a dielectric 28 (e.g., glass), thereby constituting a coaxial line.

As shown in FIG. 4, each lead pin 26 includes a shaft portion 30 inside a corresponding one of the through holes 24. Each lead pin 26 includes a first end portion 32 protruding from the first surface 12. Each lead pin 26 includes a second end portion 34 protruding from the second surface 22. The second end portion 34 is connected to the flexible printed circuit board 102 (FIG. 1).

The lead pins 26 include a signal lead pin 36. The signal lead pin 36 is thinner in the shaft portion 30 than any other of the lead pins 26. The signal lead pin 36 has the first end portion 32 larger in diameter than the shaft portion 30. The tip face of the first end portion 32 is flat.

### [Thermoelectric Cooler]

The optical module 100 has a thermoelectric cooler 38. The thermoelectric cooler 38 has an upper surface 40 and a lower surface 42. The upper surface 40 and the lower surface 42 are made of an insulator such as ceramic. The thermoelectric cooler 38 is configured to transfer heat between the upper surface 40 and the lower surface 42. The thermoelectric cooler 38 has a Peltier device 41 therein for transferring heat between the upper surface 40 and the lower surface 42. For example, the upper surface 40 is a heat absorbing surface and the lower surface 42 is a heat dissipating surface, or vice versa depending on switching. Some electrodes of the thermoelectric cooler 38 are connected to the lead pins 26 with wires W1.

The thermoelectric cooler 38 has a conductive film 44 on an upper surface 40. The conductive film 44 is a reference potential plane (e.g., ground plane). A thermistor 46 rests on the conductive film 44 to be electrically connected, enabling measurement of temperature. The thermistor 46 is connected to the lead pin 26 with a wire W2, to apply a voltage thereto.

The thermoelectric cooler 38 has a lower surface 42 secured to the first surface 12. As shown in FIG. 4, a non-conductive adhesive 48 is interposed between the thermoelectric cooler 38 and the first surface 12. The thermoelectric cooler 38 is mounted in the mounting area 16. The non-conductive adhesive 48 is interposed between the thermoelectric cooler 38 and the mounting area 16 to bond them together. Difference in height between the reference area 14 and the mounting area 16 is more than half a thickness of the thermoelectric cooler 38.

### [Sub-Mount Substrate]

The optical module 100 has a sub-mount substrate 50. The sub-mount substrate 50 is at least indirectly fixed to the first surface 12. The thermoelectric cooler 38 is interposed between the sub-mount substrate 50 and the first surface 12. The sub-mount substrate 50 is fixed to the upper surface 40 of the thermoelectric cooler 38. The sub-mount substrate 50 is mounted on the conductive film 44.

As shown in FIG. 3, the sub-mount substrate 50 overhangs in a direction from the thermoelectric cooler 38 to the signal lead pins 36. The sub-mount substrate 50 has an edge portion above the reference area 14. The edge portion of the sub-mount substrate 50 is spaced from the conductive stem 10 (FIG. 4).

The sub-mount substrate 50 has an interconnection pattern 52. The interconnection pattern 52 is on a side, of the sub-mount substrate 50, opposite to the thermoelectric cooler 38. The interconnection pattern 52 includes a signal pattern 54. The signal pattern 54 is electrically connected to a photoelectric device 56 (optical modulator) with a wire W3 to input a high frequency signal.

The interconnection pattern 52 includes a ground pattern 58. The ground pattern 58 is connected to a back electrode (not shown) on a side opposite to a mounting surface via a through hole 60. As a result, the ground pattern 58 is electrically continuous to the conductive film 44.

The sub-mount substrate 50 has the mounting surface on which the photoelectric device 56 is mounted. The photoelectric device 56 is arranged so as to direct an optical axis in a direction parallel to the mounting surface. An unillustrated termination resistor may be provided on the sub-mount substrate 50 to prevent reflected waves of the modulated electrical signal with a high-frequency component from returning to the drive IC (not shown).

### [Photoelectric Device]

The optical module 100 has a photoelectric device 56. The photoelectric device 56 is configured to convert an optical signal and an electrical signal at least from one to another. A semiconductor laser and an optical modulator are integrated in the photoelectric device 56. A wire W4 is bonded to the semiconductor laser to apply a DC voltage thereto. The optical modulator is driven in a single-ended manner.

The photoelectric device 56 is mounted on the sub-mount substrate 50. The photoelectric device 56 (back electrode) is electrically connected to the interconnection pattern 52 (ground pattern 58). The photoelectric device 56 is an edge emitting laser configured to emit light parallel to the first surface 12. The emitted light is reflected on the mirror 62 in a direction intersecting the first surface 12.

A bypass capacitor 64 is mounted on the conductive stem 10. A back surface (one electrode) of the bypass capacitor 64 is electrically continuous to the first surface 12 and is connected to the reference potential (e.g., ground). An upper surface (another electrode) of the bypass capacitor 64 is electrically continuous to the lead pin 26 with a wire W5, to apply a voltage thereto. The voltage is also connected to the photoelectric device 56 (semiconductor laser) through the wire W4 to supply a DC voltage thereto. The bypass capacitor 64 separates the high-frequency signal superimposed on the DC signal.

### [Dielectric Block]

The optical module 100 has a dielectric block 66. The dielectric block 66 has a metallization pattern 68 on its surface. As shown in FIG. 4, the dielectric block 66 is opposed to and fixed to a tip face of the first end portion 32 of the signal lead pin 36. The metallization pattern 68 is electrically continuous to the tip face. The metallization pattern 68 is on the surface of the dielectric block 66, whereby the capacitance of the dielectric block 66 can reduce the impedance. This makes it possible to improve high frequency characteristics.

### [Wire]

The optical module 100 has signal wires 72. The signal wires 72 electrically connect the metallization pattern 68 to the interconnection pattern 52 of the sub-mount substrate 50. The signal wires 72 are bonded to the signal pattern 54. A ground wire 70 electrically connects the first surface 12 of the conductive stem 10 to the ground pattern 58. One end of the ground wire 70 is bonded to the ground pattern 58.

### [Lens Cap]

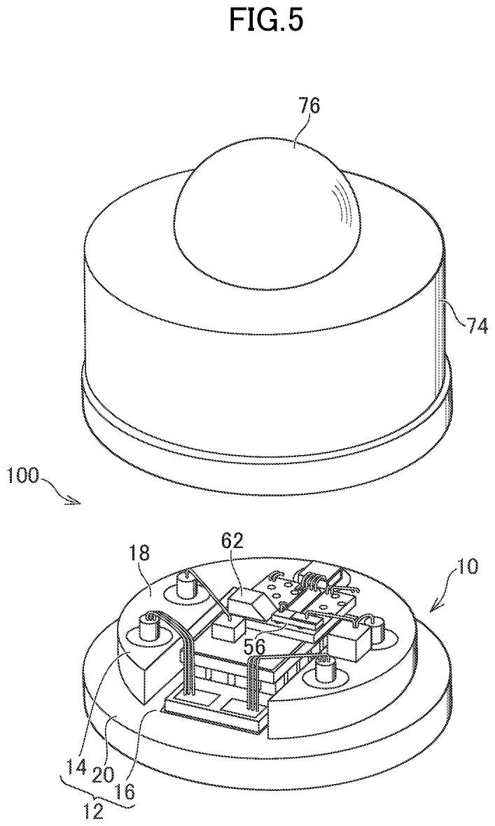

FIG. 5 is an exploded perspective view of the optical module 100. The lens cap 74 has a lens 76. The lens 76 focuses the light emitted from the photoelectric device 56 and reflected on the mirror 62. Thus, the lens 76 faces a center of the first surface 12 of the conductive stem 10. Correspondingly, the mirror 62 is also located at the center of the first surface 12 of the conductive stem 10. The lens cap 74 is attached to the conductive stem 10 using the projection 18 as a guide.

### Second Embodiment

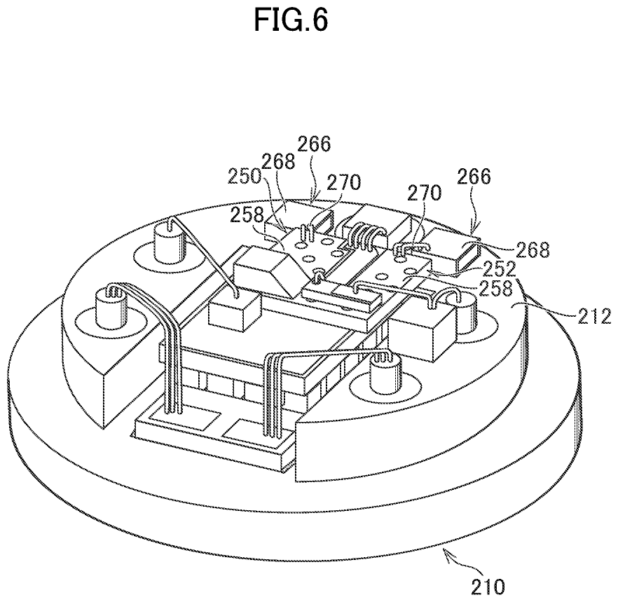

FIG. 6 is a perspective view of a conductive stem and electronic components mounted on it according to a second embodiment.

The second dielectric block 266 has the second metallization pattern 268 on the surface. The second dielectric block 266 is mounted to the first surface 212 of the conductive stem 210. The second metallization pattern 268 is electrically continuous to the conductive stem 210. The ground wire 270 electrically connects the second metallization pattern 268 to the interconnection pattern 252 (ground pattern 258) of the sub-mount substrate 250. What is described in the first embodiment is applicable to other contents.

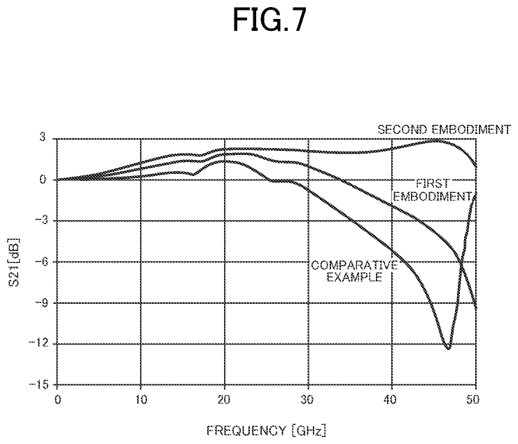

FIG. 7 is frequency characteristics of a comparative example, the first embodiment, and the second embodiment, calculated by a three-dimensional electromagnetic field simulator HFSS (High Frequency Structure Simulator). In the comparative example, the signal wire was bonded directly to the signal lead pin. It can be seen that the transmission characteristics, especially at 30 GHz or higher, are improved by compensating the inductance parasitic on the wire.

### Outline of the Embodiments

(1) An optical module 100 comprising: a conductive stem 10 having a first surface 12 and a second surface 22, the conductive stem 10 having some through holes 24 penetrating between the first surface 12 and the second surface 22; some lead pins 26 including a signal lead pin 36, the lead pins 26 being located inside the respective through holes 24, the lead pins 26 being secured to and insulated from the conductive stem 10 with a dielectric 28; a sub-mount substrate 50 having an interconnection pattern 52, the sub-mount substrate 50 being at least indirectly fixed to the first surface 12; a photoelectric device 56 mounted on the sub-mount substrate 50 and electrically connected to the interconnection pattern 52, the photoelectric device 56 being configured to convert an optical signal and an electrical signal at least from one to another; a dielectric block 66 having a metallization pattern 68 on a surface; and a signal wire 72 electrically connecting the metallization pattern 68 to the interconnection pattern 52 of the sub-mount substrate 50, each of the lead pins 26 including a shaft portion 30 inside a corresponding one of the through holes 24, a first end portion 32 projecting from the first surface 12, and a second end portion 34 projecting from the second surface 22, the signal lead pin 36 having the first end portion 32 larger in diameter than the shaft portion 30, the dielectric block 66 being opposed to and fixed to a tip face of the first end portion 32 of the signal lead pin 36, the metallization pattern 68 being electrically continuous to the tip face.

(2) The optical module according to (1), further comprising: a second dielectric block 266 having a second metallization pattern 268 on a surface, the second dielectric block 266 being mounted on the first surface 212 of the conductive stem 210, the second metallization pattern 268 being electrically continuous to the conductive stem 210; and a ground wire 270 electrically connecting the second metallization pattern 268 to the interconnection pattern 252 of the sub-mount substrate 250, wherein the interconnection pattern 252 of the sub-mount substrate 250 includes a signal pattern 54 to which the signal wire 72 is bonded and a ground pattern 258 to which the ground wire 270 is bonded.

(3) The optical module 100 according to (1) or (2), further comprising a thermoelectric cooler 38 interposed between the sub-mount substrate 50 and the first surface 12.

(4) The optical module 100 according to (3), further comprising a non-conductive adhesive 48 interposed between the thermoelectric cooler 38 and the first surface 12.

(5) The optical module 100 according to (3) or (4), wherein the first surface 12 of the conductive stem 10 includes a reference area 14 where the lead pins 26 are arranged and a mounting area 16 that is lower than the reference area 14 and in which the thermoelectric cooler 38 is mounted.

(6) The optical module 100 according to (5), wherein the sub-mount substrate 50 overhangs in a direction from the thermoelectric cooler 38 to the signal lead pin 36 and has an edge portion above the reference area 14.

(7) The optical module 100 according to (6), wherein the edge portion of the sub-mount substrate 50 is spaced from the conductive stem 10.

(8) The optical module 100 according to any one of (5) to (7), wherein the first surface 12 of the conductive stem 10 has a projection 18 around the mounting area 16, the projection 18 having an upper surface as the reference area 14, the first surface 12 of the conductive stem 10 having a peripheral area 20 around the projection 18, the peripheral area 20 being lower than the reference area 14, the optical module 100 further comprising a lens cap 74 attached to the conductive stem 10 using the projection 18 as a guide.

(9) The optical module 100 according to any one of (1) to (8), wherein the photoelectric device 56 is an edge emitting laser configured to emit light parallel to the first surface 12, the optical module 100 further comprising a mirror 62 configured to reflect the light in a direction intersecting the first surface 12.

(10) The optical module 100 according to any one of (1) to (9), wherein the signal lead pin 36 is thinner at the shaft portion 30 than any other of the lead pins 26.

The embodiments described above are not limited and different variations are possible. The structures explained in the embodiments may be replaced with substantially the same structures and other structures that can achieve the same effect or the same objective.

What is claimed is:

1. An optical module comprising:
a conductive stem having a first surface and a second surface, the conductive stem having some through holes penetrating between the first surface and the second surface;
some lead pins including a signal lead pin, the lead pins being located inside the respective through holes, the lead pins being secured to and insulated from the conductive stem with a dielectric;
a sub-mount substrate having an interconnection pattern, the sub-mount substrate being at least indirectly fixed to the first surface;
a photoelectric device mounted on the sub-mount substrate and electrically connected to the interconnection pattern, the photoelectric device being configured to convert an optical signal and an electrical signal at least from one to another;
a dielectric block having a metallization pattern on a surface; and
a signal wire electrically connecting the metallization pattern to the interconnection pattern of the sub-mount substrate,
each of the lead pins including a shaft portion inside a corresponding one of the through holes, a first end portion projecting from the first surface, and a second end portion projecting from the second surface,
the signal lead pin having the first end portion larger in diameter than the shaft portion,
the dielectric block being opposed to and fixed to a tip face of the first end portion of the signal lead pin, the metallization pattern being electrically continuous to the tip face.

2. The optical module according to claim 1, further comprising:
a second dielectric block having a second metallization pattern on a surface, the second dielectric block being mounted on the first surface of the conductive stem, the second metallization pattern being electrically continuous to the conductive stem; and
a ground wire electrically connecting the second metallization pattern to the interconnection pattern of the sub-mount substrate,
wherein the interconnection pattern of the sub-mount substrate includes a signal pattern to which the signal wire is bonded and a ground pattern to which the ground wire is bonded.

3. The optical module according to claim 1, further comprising a thermoelectric cooler interposed between the sub-mount substrate and the first surface.

4. The optical module according to claim 3, further comprising a non-conductive adhesive interposed between the thermoelectric cooler and the first surface.

5. The optical module according to claim 3, wherein the first surface of the conductive stem includes a reference area where the lead pins are arranged and a mounting area that is lower than the reference area and in which the thermoelectric cooler is mounted.

6. The optical module according to claim 5, wherein the sub-mount substrate overhangs in a direction from the thermoelectric cooler to the signal lead pin and has an edge portion above the reference area.

7. The optical module according to claim 6, wherein the edge portion of the sub-mount substrate is spaced from the conductive stem.

8. The optical module according to claim 5, wherein the first surface of the conductive stem has a projection around the mounting area, the projection having an upper surface as the reference area, the first surface of the conductive stem having a peripheral area around the projection, the peripheral area being lower than the reference area,
the optical module further comprising a lens cap attached to the conductive stem using the projection as a guide.

9. The optical module according to claim 1, wherein the photoelectric device is an edge emitting laser configured to emit light parallel to the first surface,
the optical module further comprising a mirror configured to reflect the light in a direction intersecting the first surface.

10. The optical module according to claim 1, wherein the signal lead pin is thinner at the shaft portion than any other of the lead pins.
